(19) United States
(12) Patent Application Publication
(10) Pub. No.: US 2003/0029637 A1
(43) Pub. Date: Feb. 13, 2003

(54) Circuit board assembly with ceramic capped components and heat transfer vias

(76) Inventor: Tina Barcley, Mendon, NY (US)

Correspondence Address: Edwin W. Bacon, Jr., DaimlerChrysler Intellectual Capital Corporation, CIMS 483-02-19, 800 Chrysler Drive, Auburn Hills, MI, 48326-2757, US

(21) Appl. No.: 09/928,584

(22) Filed: Aug. 13, 2001

(51) Int. Cl. H05K 1/11

(52) U.S. Cl. 174/262

(57) ABSTRACT

A circuit board assembly is provided having a multiple layer printed circuit board. A ceramic surface mounted device is provided having first and second end caps. First and second electrically conductive pads support respective first and second ends of the surface mounted device above the printed circuit boards. The pads are soldered to the end caps. One of the pads supplies power and the other pad serves as a ground. A heat sink is positioned adjacent the printed circuit board opposite the pads and is separated from the printed circuit board by a thermally conductive electrically insulating adhesive. A plurality of thermal vias are deposited in each of the pads thermally connecting the first and second pads with respective third and fourth pads generally on the opposite side of the circuit board.

### FIELD OF THE INVENTION

The present invention relates generally to circuit board assemblies and more particularly, to flexible printed circuit boards utilized for thin profile electronic control assemblies which are positioned in harsh environments such as automotive vehicles.

### BACKGROUND OF THE INVENTION

In the most recent half century there has been a significant increase in the use of electronics for control of various functions in automotive vehicles. Many of the control functions currently achieved by electronics were previously performed by hydraulic or pneumatic control systems. For example, virtually all automotive vehicles have an engine control by an electronic engine control module to optimize the performance of the engine in regard to emissions and fuel economy. Advance braking systems have been provided such as a traction control and anti-skid braking to enhance safe operation of a vehicle. To further enhance fuel economy, most vehicles with an automatic transmission are electronically controlled. Many of the electronic controllers must function in a harsh environment of the engine compartment. Within engine compartments, the temperature can easily reach and/or exceed 140 degrees centigrade.

Typically, the space within the engine compartment is at a premium since it is desirable to keep the engine compartment as small as possible in order to maximize the aerodynamic efficiency of the vehicle. To meet the space constraints, many automotive electronic controllers are provided on flexible circuit boards which can be folded and then placed in an appropriate housing. The circuit boards typically utilized are heavily populated with electronic traces and components. It is desirable that such circuit boards have a thin (low height) profile. Examples of flexible circuit board assemblies can be found by a review of U.S. Pat. No. 5,924,873 and U.S. patent application Ser. No. 09/574,634 entitled “Multiple Layer Thin Flexible Circuit Board” Barcley, filed May 18, 2000, commonly assigned. The disclosure of Barcley, Ser. No. 09/574,634 is incorporated by reference herein. To minimize the cost and vertical height of the electronic components on many circuit board assemblies, electrical components with end caps (sometimes referred to as leadless components) are preferred.

FIG. 1 of the drawings illustrates a prior art circuit board assembly. Circuit board assembly 9 includes a rigidizer 10. The rigidizer is typically provided by a steel or aluminum plate. On top of the rigidizer 10 and bonded thereto is a film of adhesive 12. The adhesive 12 is thermally conductive but electrically performs the function of a dielectric. The thermal conductivity of the adhesive 12 allows the rigidizer to act as a heat sink. The adhesive 12 is bonded with a printed circuit board 14. The printed circuit board as shown has four layers 16, 18, 19 and 20. In other examples (not shown) the circuit board may have five, six, seven, but generally not more than eight layers depending upon the preference of the control designer. Placed upon a top surface 24 of the circuit board is a surface mounted device 26. The surface mounted device 26 as shown is a film resistor having a ceramic core 28. However, the device 26 can also be a capacitor or other electrical device. The surface mounted device 26 has a first end 30 and a second end 32. The first and second ends 30 and 32 are encapsulated by respective end caps 34 and 36. The end caps 34 and 36 are electrically connected to conductive pads 38 and 40 respectively. Each of the conductive pads has a plated layer 42 which may be of tin/lead or other suitable metal to protect an underlying copper layer from corrosion. The copper pads 38 and 40 are electrically connected by soldering or other suitable means with leads 46, 47 respectively, which are printed on the printed circuit board 14.

The surface mounted device 26 in very cold weather can go down to temperatures of −40 degrees centigrade and below. In operation, the surface mounted device 26 can see temperatures approaching 135 degrees centigrade. Accordingly, the surface mounted device 26 can see a temperature differential of 175 degrees centigrade, which is approximately equal to 315 degrees Fahrenheit. The coefficient of thermal expansion of the ceramic material of the surface mounted device 26 is approximately 6×10⁶ inches per inch degree Fahrenheit. The coefficient of thermal expansion of the circuit board is in the range of 15×10⁻⁶ inches per inch degree Fahrenheit. The device 26 is connected to the circuit board 14 via solderings 48, 49. The soldering 48 is joined to the pad 38. The pad 38 which is primarily copper has a coefficient of thermal expansion of 9.8×10⁻⁶ inches per inch degree Fahrenheit. The dimensions of FIG. 1 have been exaggerated for clarity of illustration. Typically, the printed circuit board will be between 0.0125 and 0.031 inches thick. The pad 38 will typically be 0.0014 to 0.0008 inches thick. If a 2512 PRNDL resistor is utilized, the resistor length is 0.250 inches. The expansion movement will typically be equalized, half of it to the right and half of it to the left. Accordingly, multiplying the length of ½ of the resistor 0.125 inches times a movement of 0.00189 inches per inch (which occurs due to the 315 degree Fahrenheit temperature differential) results in a rightward movement of approximately 0.00024 inches. The copper pad 38 is approximately 0.120 inches wide and 0.100 inches long. Accordingly, the delta movement of the copper will be 0.003087 inches per inch times 0.050 inches resulting in a delta movement of 0.00015 inches. The copper pad 38 moves a total distance that is less than that of the resistor moving on top of it (a delta of 0.0009 inches). The solder 48, which is holding the copper pad 38 to the resistor 26 has to make up for this delta. The solder has a coefficient of thermal expansion of 13×10⁻⁶. inches per inch degree Fahrenheit. The soldering joint is approximately 0.050 inches wide in its lengthwise direction. The copper will push the entire width of the solder, so therefore the delta movement for 315 degrees Fahrenheit is 0.004095 times 0.050 resulting in 0.0020 inches. The solder absorbs a delta movement of 0.00020 inches. The “push” is the difference between the copper moving less than the ceramic. Accordingly, the push is 0.00024 minus 0.00015 inches. Since 0.00009 inches is less than 0.00020 inches, the solder joint 48 will not fracture upon the first cycle that it undergoes in testing. With normal aging, as the circuit board assembly 9 is utilized in a vehicle, this difference will “creep”. Creep will progress until the stress is built up and the solder overwhelms the strength of the solder and causes a crack. This tendency toward creep can have a major impact upon connection durability. To alleviate the creep, the best technique is to reduce the maximum temperature differential which causes the stress to be generated. Lowering the temperature differential accordingly lowers creep and causes the circuit board assembly 9 to have greater reliability. The aforementioned delta movement is mainly between the copper pad and the component. Any heat removed from the component (resistor 26 body) will make it move less which will reduce the delta movement. Additionally, any heat removed from the copper pad 38 will additionally reduce movement since the copper pad 38 acts as a sink for the resistor 26.

It is desirable to provide a circuit board assembly wherein heat can be removed from the component and/or the copper pad in order to reduce the stress induced by the differential in thermal expansion coefficients of the copper pad and the surface mounted device. This desire is especially crucial when the surface mounting device length extends beyond 0.20 inches.

### SUMMARY OF THE INVENTION

To make manifest the above noted desire, a revelation of the present invention is brought forth. In a preferred embodiment, the present invention brings forth a circuit board assembly which includes a printed circuit board. It is provided having first and second ends. First and second electrically conductive pads are provided for supporting the respective first and second ends of the surface mounted device above the printed circuit board. One of the pads is a voltage, signal or power supply and the other pad serves as a ground. A heat sink is provided adjacent the printed circuit board opposite the first and second pads. The heat sink is separated from the printed circuit board by a thermally conductive electrically insulating adhesive. A plurality of thermal vias are deposited in the pads and thermally connect the first and second pads with respective third and fourth pads generally on an opposite side of the circuit board. The third and fourth pads are thermally connected with the heat sink via the adhesive.

In a second alternative embodiment of the present invention, the thermal vias are placed in the circuit board between the pads directly underneath the surface mounted device in a manner similar to that described above. The vias conduct heat away from the surface mounted device to the heat sink which is on the opposite side of the printed circuit board.

It is a feature of the present invention to provide a circuit board assembly having thermal vias to lower the temperature of a capped ceramic surface mounted device in order to reduce a differential in thermal expansion between the surface mounted device and a conductive pad that is soldered thereto.

Other features of the invention will become more apparent to those skilled in the art from a review of the invention from the accompanying drawings and detailed description.

### BRIEF DESCRIPTION OF THE DRAWINGS

FIG. 1 is a prior art sectional view of a circuit board assembly.

FIG. 2 is a sectional view of a preferred embodiment circuit board assembly according to the present invention.

FIG. 3 is a top elevational view of a circuit board assembly shown in FIG. 2.

FIG. 4 is a side elevational view of an alternate preferred embodiment circuit board assembly according to the present invention.

FIG. 5 is a view similar to FIG. 2 of another alternate preferred embodiment of the present invention.

FIG. 6 is an enlarged view of a portion of FIG. 2.

### DETAILED DESCRIPTION OF THE INVENTION

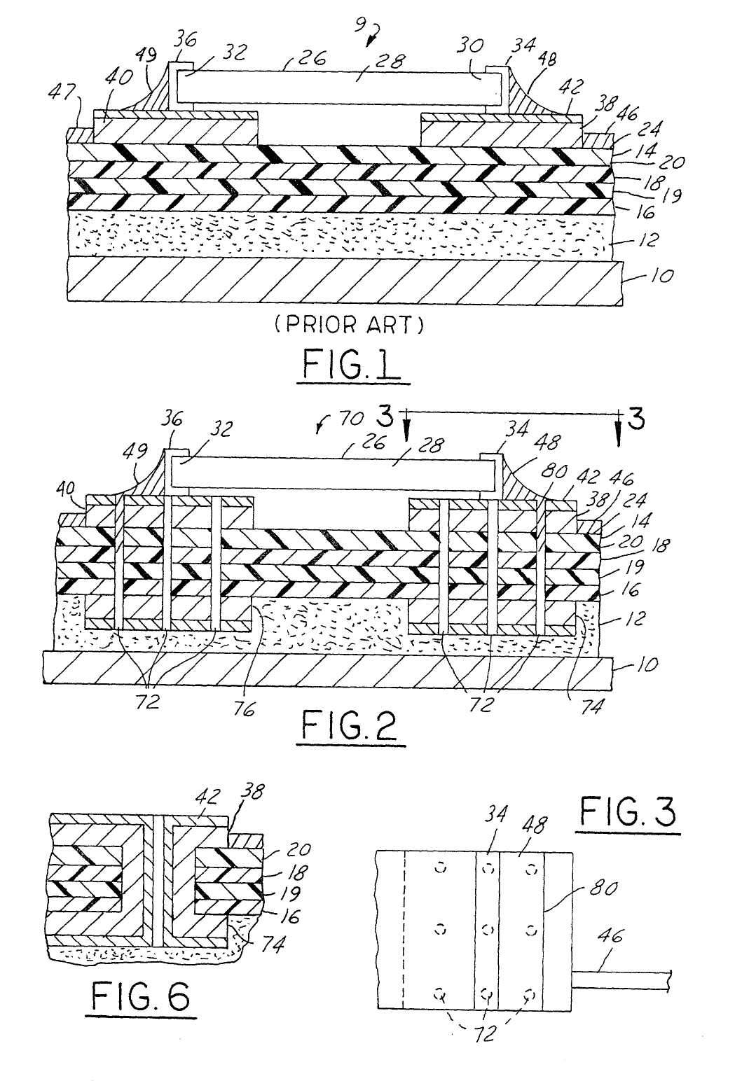

FIGS. 2-6 illustrate the present invention and have identical reference numbers to similar items found in prior art FIG. 1. Turning to FIG. 2, the present inventive circuit board assembly 70 has a rigidizer 10. The rigidizer 10 also functions as a heat sink. Adjacent to the rigidizer 10 is a layer or film adhesive 12. The adhesive 12 is electrically insulating and can be a liquid adhesive, Dow Corning 1-4175 manufactured by the Dow Corning Corporation, Midland, Mich. Glass beads (not shown) can also be utilized as spacers.

The circuit board assembly 70 has a multi-layered bonded printed circuit board 14. A first or top layer 20 is provided for the general placement of electronic components and their connections (as is well known in the art) to the traces or leads 46 and the thermal pads 38, 40. A second layer 18 generally contains horizontal traces (not shown) for connecting components that may be placed upon the first layer 20. The second layer 18 also has grounding and some connections for a connector harness (not shown). A third layer 16 generally contains the vertical traces (not shown) as is known in the art. The printed circuit board 14 may also have a fourth layer 19. The fourth layer 19 is a general ground. The layers 16, 18, 19 can be stacked in any order. The layers have 2 mil cores and are flexible and commercially available from Photocircuits, Glen Cove, N.Y. under the designation flexible FR-406. The printed circuit board 14 is generally known as FR-4, however the present invention can be used on other printed circuit boards which may be polymeric, polyamide, ceramic, rigid or flexible or other suitable substitutes.

The first thermally electrically conductive pad 38 is bonded to the printed circuit board 14. The pad 38 contains a plurality of thermal vias (or holes) 72. The printed circuit board 14 as mentioned previously, contains the layers 16, 18, 19 and 20 bonded together, the order of which can be dictated by the design. Once the layers are bonded the thermal vias 72 are formed through all layers of the printed circuit board. The thermal vias are formed in a predetermined pattern and size. However, in an embodiment of the invention (not shown) different patterns of vias may be utilized based on an area of the pads 38, 40. Once the thermal vias 72 are drilled in the printed circuit board 14 then a thin layer 42 is plated onto the printed circuit board in the area of the pads 38, 40 and on the walls of the thermal vias. The area is then plated again with the same or a different material. The thermally conductive material of the pad is preferably copper. Layer 42 can be a variety of materials such as palladium, nickel-gold, immersion silver, immersion tin, or OSP, which is an organic. The layer 42 not only extends into the vias 72 but also plates the top of the pad 38.

On an opposite side of the printed circuit board 14 are third and fourth pads 74, 76. The pads 74, 76 are intersected by the vias 72. Pads 74, 76 increase the effectiveness of the vias 72 by providing thermal spreaders to the adhesive 12. The pads 74, 76 are substantially similar if not identical to pads 38, 40. For high heat applications, pads 38, 40 can be made larger for more efficiency. The thermal vias are approximately 0.022 inches in diameter with a lateral hole-to-hole spacing of 0.04 inches and a longitudinal hole spacing of 0.05 inches in an array of six vias per pad. For a smaller chip device such as 2010, five vias would be utilized in a 2-1-2 arrangement with a cross-lateral, center-to-center distance of 0.049 inches. In a 1210 chip device, three vias per pad design is provided with a 0.036 cross-lateral spacing.

Referring additionally to FIG. 3, as mentioned previously, the resistor 26 is reflow or hand-soldered onto the pads 38, 40. Then, while the solder 48 is flowing it may fill the thermal vias 72 on the extreme end 80 of the solder. The solder 48 can come into contact with the adhesive 12.

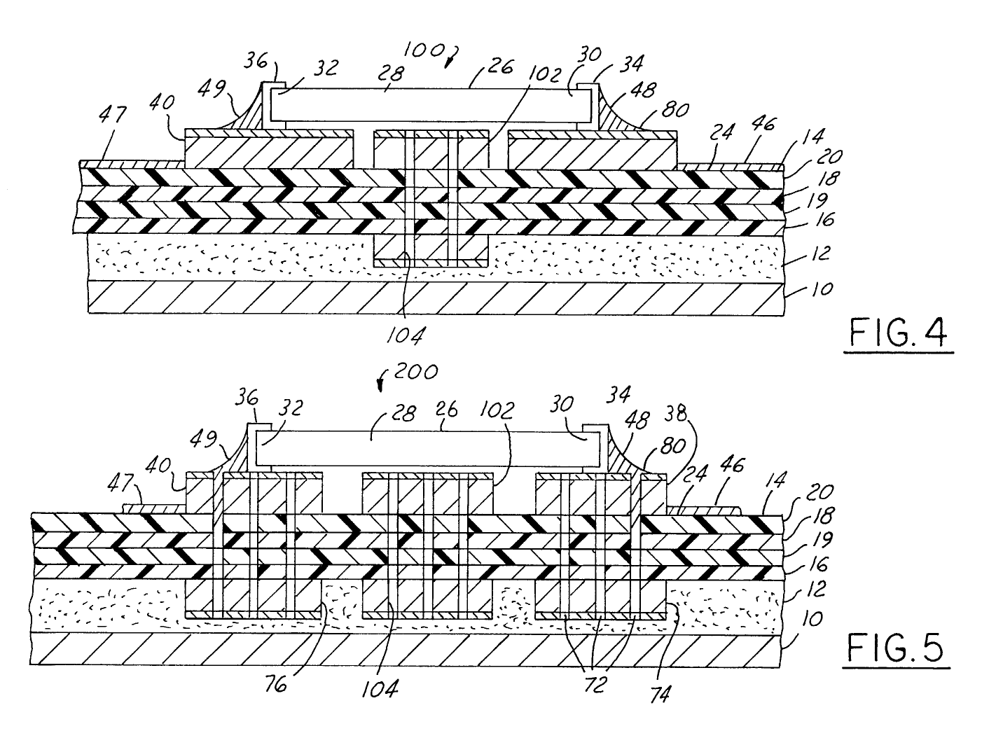

Referring to FIG. 4, with items performing similar functions being given identical numbers, a circuit board assembly 100 is provided. The circuit board assembly 100 has a pad 102 underneath the device 26. The pad 102 is similar to pads 38, 40 except that it has a collection of nine 0.022 diameter thermal via holes 104. The holes 104 have a longitudinal spacing of 0.050 inches and a lateral spacing of 0.040 inches. Other via diameters and spacings can be utilized.

In operation, referring back to FIG. 2 the thermal vias in the pads 38, 40 result in a temperature reduction in the device 26 of approximately 50%. The 50% reduction significantly reduces the creep stress in the solder.

In operation, referring back to FIG. 4 the thermal vias in the pads 102 underneath the device 26 reduces the temperature rise by approximately 20%. The 20% reduction is also significant. The circuit assembly 100 may be preferable in some applications wherein the circuit board assembly is being utilized in a high vibration environment since the pads will not have vias drilled in them which may decrease the strength of the solder joint.

Referring to FIG. 5, with similar functions being given identical numbers, a circuit board assembly 200 is provided. The circuit board assembly has pads 38 and 40 with thermal vias 72. The circuit board assembly 200 additionally has a pad 102 underneath the device 26. The circuit board assembly 200 is for applications where cooling is at a premium.

While preferred embodiments of the present invention have been disclosed, it is to be understood that they have been disclosed by way of example only and that various modifications can be made without departing from the spirit and scope of the invention as it is encompassed by the following claims.

I claim:

1. A circuit board assembly comprising:
a printed circuit board;
a surface mounted ceramic device having first and second ends with end caps;
first and second electrically conductive pads supporting respective said first and second ends of said device above said printed circuit board, said first and second pads being soldered to said device respective first and second end caps;
a heat sink positioned adjacent said printed circuit board opposite said pads; and
at least one cylindrical thermal via deposited into said printed circuit board thermally connecting each said pad with said heat sink.

2. A circuit board assembly as described in claim 1, wherein said surface mounted device is a resistor.

3. A circuit board assembly as described in claim 1, wherein said printed circuit board is a multi-layered printed circuit board.

4. A circuit board assembly as described in claim 1, wherein said heat sink includes an electrically conductive rigidizer plate and wherein said rigidizer plate is insulated from said circuit board by an electrically insulating thermally conductive adhesive.

5. A circuit board assembly as described in claim 1 having a plurality of thermal vias.

6. A circuit board assembly as described in claim 1, wherein said vias includes solder which is utilized to electrically connect said surface mounted device end caps with said pad and wherein said solder flows into said via providing a solid thermal path.

7. A circuit board assembly as described in claim 1, having a pad on said circuit board generally opposite said pad supporting said surface mounted device and wherein said via thermally intersects both of said pads.

8. A circuit board assembly as described in claim 1, wherein said via is fabricated from a material said pad is formed from.

9. A circuit board assembly as described in claim 8, wherein said via is plated with a material plating said pad.

10. A circuit board assembly comprising;
a multiple layer printed circuit board;
a surface mounted ceramic device having first and second ends with end caps;
first and second electrically conductive pads supporting respective said first and seconds ends of said device above said printed circuit board, said first and second pads being soldered to said first and second end caps;
a heat sink positioned adjacent said printed circuit board opposite said pads and separated from said printed circuit board by a thermally conductive electrically insulating adhesive; and
a plurality of cylindrical thermal vias deposited in said printed circuit board pads thermally connecting said first and second pads with respective third and fourth pads generally on an opposite side of said circuit board, said third and fourth pads being thermally connected via said adhesive with said heat sink.

11. A circuit board assembly comprising;
a printed circuit board;
a ceramic surface mounted device having first and second ends with first and second end caps on said ends;
first and second electrically conductive pads supporting said first and second ends of said device above said printed circuit board, said first and second pads being soldered to said first and second end caps;
a heat sink positioned adjacent said printed circuit board opposite said pads; and
at least a first cylindrical thermal via deposited in said printed circuit board underneath said surface mounted device thermally connected with said heat sink.

12. A circuit board assembly as described in claim 11, wherein said surface mounted device is a resistor.

13. A circuit board assembly as described in claim 11, wherein said printed circuit board is a multi-layered board.

14. A circuit board assembly as described in claim 11, wherein said printed circuit board has a thermally conductive plate intersecting said via opposite said device and said plate is connected to said circuit board via an electrically insulating and thermally conductive adhesive.

15. A circuit board assembly as described in claim 11 having at least one cylindrical thermal via deposited into said printed circuit board thermally connecting on e of said pad s with said heat sink.

16. A circuit board assembly as described in claim 11, wherein said thermal via is connected with a pad on said printed circuit board underneath said surface mounted device.

17. A circuit board assembly as described in claim 11, wherein said via is fabricated from a material said pad is formed from.

18. A circuit board assembly as described in claim 11 having a plurality of thermal vias.

19. A circuit board assembly as described in claim 11, wherein said via intersects a pad on a side of said circuit board opposite said pad underneath said surface mounted device.
